(19) United States
(12) Patent Application Publication
(10) Pub. No.: US 2019/0156761 A1
(43) Pub. Date: May 23, 2019

(54) TIMING CONTROLLER MODULATING A GATE CLOCK SIGNAL AND DISPLAY DEVICE INCLUDING THE SAME

(71) Applicant: SAMSUNG DISPLAY CO., LTD., Yongin-si (KR)

(72) Inventors: Yunmi Kim, Changwon-si (KR); Kihyun Pyun, Gwangmyeong-si (KR); Sung-in Kang, Seoul (KR)

(21) Appl. No.: 16/186,925

(22) Filed: Nov. 12, 2018

(30) Foreign Application Priority Data
Nov. 17, 2017 (KR) 10-2017-0154321

(51) Int. Cl. G09G 3/3266; G09G 3/36; H03L 7/099; H03L 7/089; H03L 7/197

(52) U.S. Cl. CPC G09G 3/3266; G09G 3/3677; H03L 7/099; H03L 7/0891; G09G 2310/0297; G09G 2310/08; G09G 2310/06; G09G 2310/0291; H03L 7/197

(57) ABSTRACT

A timing controller of a display device controls a gate driver of the display device. The timing controller includes a clock generator configured to provide a gate clock signal to the gate driver by modulating the gate clock signal with a first modulation pattern in a first frame period and by modulating the gate clock signal with a second modulation pattern different from the first modulation patter in a second frame period.

### CROSS-REFERENCE TO RELATED APPLICATION(S)

This application claims priority under 35 USC § 119 to Korean Patent Application No. 10-2017-0154321, filed on Nov. 17, 2017 in the Korean Intellectual Property Office (KIPO), the contents of which are incorporated by reference in its entirety.

### TECHNICAL FIELD

Exemplary embodiments of the present inventive concept relate to a display device, and more particularly to modulating a gate clock signal provided to a gate driver for using with a display device.

### DESCRIPTION OF THE RELATED ART

A display device generally includes a display panel that has a matrix of pixels. A pixel includes at least one switching transistor that has a gate terminal connected to a gate line receiving gate signals from a gate driver. The gate driver may generate the gate signals based upon a gate clock signal received from a timing controller. The gate clock signal provided by the timing controller may be a periodic signal with a single time period for each cycle of the gate clock signal. The Fourier transform of the periodic signal has spectra peaks at a fundamental frequency and its harmonics, with the fundamental frequency being equal to the inverse of the signal time period. When the gate clock signal provided by the timing controller is a periodic signal with a single time period, the electro-magnetic interference (EMI) caused by a display device may also have spectra peaks at the fundamental frequency and its harmonics. The EMI caused by a display device may be reduced, if the gate clock signal provided by the timing controller is a spread spectrum clock signal in which the time period of the clock cycles constantly changes with time. Exemplary embodiments of the present inventive concept relate to modulating the gate clock signal provided to the gate driver for using with a display device.

### SUMMARY

Some example embodiments provide a timing controller capable of reducing horizontal line defects or black noise caused by gate clock signals while reducing electro-magnetic interference (EMI).

Some example embodiments provide a display device including a timing controller capable of reducing horizontal line defects or black noise caused by gate clock signals while reducing EMI.

According to example embodiments, there is provided a timing controller for using with a display device. The timing controller includes an output terminal operative to provide a gate clock signal to a gate driver of a display device, and a clock generator operative to generate the gate clock signal by modulating the gate clock signal with a first modulation pattern in a first frame period and by modulating the gate clock signal with a second modulation pattern different from the first modulation pattern in a second frame period.

In example embodiments, the first modulation pattern and the second modulation pattern may be different in at least one of modulation period, modulation amount and modulation phase from each other.

In example embodiments, the second modulation pattern may be inverted from the first modulation pattern with respect to a reference frequency.

In example embodiments, if the gate clock signal modulated with the first modulation pattern in the first frame period has a frequency higher than a reference frequency at a time point when a gate signal for one gate line of a plurality of gate lines is generated, the gate clock signal modulated with the second modulation pattern in the second frame period may have a frequency lower than the reference frequency at a time point when the gate signal for the one gate line is generated.

In example embodiments, a modulation period of the first and second modulation patterns may be substantially identical to one frame period.

In example embodiments, each of the first and second frame periods may be equally divided into a first sub-period, a second sub-period, a third sub-period and a fourth sub-period. A frequency of the gate clock signal modulated with the first modulation pattern may increase from a reference frequency to a maximum frequency during the first sub-period of the first frame period, may decrease from the maximum frequency to the reference frequency during the second sub-period of the first frame period, may decrease from the reference frequency to a minimum frequency during the third sub-period of the first frame period, and may increase from the minimum frequency to the reference frequency during the fourth sub-period of the first frame period. The frequency of the gate clock signal modulated with the second modulation pattern may decrease from the reference frequency to the minimum frequency during the first sub-period of the second frame period, may increase from the minimum frequency to the reference frequency during the second sub-period of the second frame period, may increase from the reference frequency to the maximum frequency during the third sub-period of the second frame period, and may decrease from the maximum frequency to the reference frequency during the fourth sub-period of the second frame period.

In example embodiments, the clock generator may include a phase locked loop circuit configured to generate the gate clock signal in response to an input clock signal, and a modulation control circuit configured to control the phase locked loop circuit to modulate the gate clock signal.

In example embodiments, the phase locked loop circuit may include a programmable divider, and the modulation control circuit may control the phase locked loop circuit to modulate the gate clock signal by changing a divider value of the programmable divider.

In example embodiments, the phase locked loop circuit may include a phase frequency detector configured to generate an error signal corresponding to a phase difference between the input clock signal and a feedback clock signal, a charge pump configured to generate a current corresponding to the error signal, a loop filter configured to convert the current generated by the charge pump into a control voltage, a voltage controlled oscillator configured to generate the gate clock signal having a frequency corresponding to the control voltage, and a programmable divider configured to receive a divider value from the modulation control circuit, and to generate the feedback clock signal by dividing the gate clock signal by the received divider value.

In example embodiments, the modulation control circuit may include a modulation profile circuit configured to store a reference modulation pattern, and an inversion circuit configured to output the reference modulation pattern as the first modulation pattern in the first frame period, and to invert the reference modulation pattern with respect to a reference frequency to output the inverted reference modulation pattern as the second modulation pattern in the second frame period.

In example embodiments, the modulation profile circuit may include a divider value table configured to store a plurality of divider values corresponding to the reference modulation pattern.

In example embodiments, the inversion circuit may include a buffer configured to buffer the divider values sequentially output from the divider value table, an inverter configured to invert the divider values sequentially output from the divider value table, and a multiplexer configured to selectively output the buffered divider values output from the buffer or the inverted divider values output from the inverter in response to a modulation control signal that is inverted after each frame period.

According to example embodiments, there is provided a timing controller for using with a display device. The timing controller includes an output terminal operative to provide a gate clock signal to a gate driver of a display device and a clock generator configured to store a plurality of modulation patterns, to sequentially select the plurality of modulation patterns, and to modulate the gate clock signal with a selected one of the plurality of modulation patterns.

In example embodiments, the plurality of modulation patterns may be different in at least one of modulation period, modulation amount and modulation phase from each other.

In example embodiments, the plurality of modulation patterns may include a first modulation pattern having a modulation period corresponding to one frame period, a second modulation pattern having a modulation period corresponding to a half of a frame period, a third modulation pattern having a modulation period corresponding to a quarter of a frame period, and a fourth modulation pattern having a modulation period corresponding to one-eighth of a frame period.

In example embodiments, each frame period may be equally divided into a first sub-period, a second sub-period, a third sub-period and a fourth sub-period. The clock generator may modulate the gate clock signal with the first modulation pattern during a first frame period, may modulate the gate clock signal with the second modulation pattern during the first and second sub-periods of a second frame period, may modulate the gate clock signal with the third modulation pattern during the third sub-period of the second frame period, and may modulate the gate clock signal with the fourth modulation pattern during the fourth sub-period of the second frame period.

In example embodiments, the clock generator may include a phase locked loop circuit configured to generate the gate clock signal in response to an input clock signal, and a modulation control circuit configured to store the plurality of modulation patterns, to sequentially select the plurality of modulation patterns, and to control the phase locked loop circuit to modulate the gate clock signal with the selected one of the plurality of modulation patterns.

In example embodiments, the modulation control circuit may include a plurality of divider value tables configured to store a plurality of divider value sets corresponding to the plurality of modulation patterns, respectively, and a multiplexer configured to selectively output one of the plurality of divider value sets output from the plurality of divider value tables in response to a rotational control bit signal.

According to example embodiments, there is provided a display device including a display panel including a plurality of data lines, a plurality of gate lines, and a plurality of pixels, in which a pixel includes a switching transistor with its gate connected to a gate line. The display device further includes a data driver configured to provide data signals to the plurality of pixels through the plurality of data lines, a gate driver configured to provide gate signals to the plurality of pixels through the plurality of gate lines, and a timing controller configured to control the data driver and the gate driver. The timing controller includes a clock generator configured to provide a gate clock signal to the gate driver by modulating the gate clock signal with a first modulation pattern in a first frame period and by modulating the gate clock signal with a second modulation pattern different from the first modulation patter in a second frame period.

In example embodiments, the second modulation pattern may be inverted from the first modulation pattern with respect to a reference frequency.

As described above, the timing controller and the display device according to example embodiments may modulate the gate clock signal with the first modulation pattern in the first frame period, and may modulate the gate clock signal with the second modulation pattern different from the first modulation pattern in the second frame period, thereby reducing the horizontal line defect or the black noise caused by the modulation of the gate clock signal while reducing the EMI.

### BRIEF DESCRIPTION OF THE DRAWINGS

Illustrative, non-limiting example embodiments will be more clearly understood from the following detailed description in conjunction with the accompanying drawings. For the purposes of this disclosure, “at least one of X, Y, and Z” may be construed as X only, Y only, Z only, or any combination of two or more of X, Y, and Z, such as, for instance, XYZ, XYY, YZ, and ZZ. Like numbers refer to like elements throughout.

FIG. 1 is a block diagram illustrating a display device according to example embodiments.

FIG. 2 is a block diagram illustrating a clock generator included in a timing controller according to example embodiments.

FIG. 3 is a block diagram illustrating a clock generator included in a timing controller according to example embodiments.

FIG. 4 is a timing diagram illustrating an example of a frequency of a gate clock signal generated by a clock generator include in a timing controller according to example embodiments.

FIG. 5 a diagram of a display panel for describing an effect of reducing a horizontal line defect of a black noise by a gate clock signal having a frequency illustrated in FIG. 5 according to example embodiments.

FIG. 6 is a block diagram illustrating a clock generator included in a timing controller according to example embodiments.

FIG. 7 is a timing diagram illustrating an example of a frequency of a gate clock signal generated by a clock generator include in a timing controller according to example embodiments.

### DETAILED DESCRIPTION OF THE EMBODIMENTS

Hereinafter, embodiments of the present inventive concept will be explained in detail with reference to the accompanying drawings.

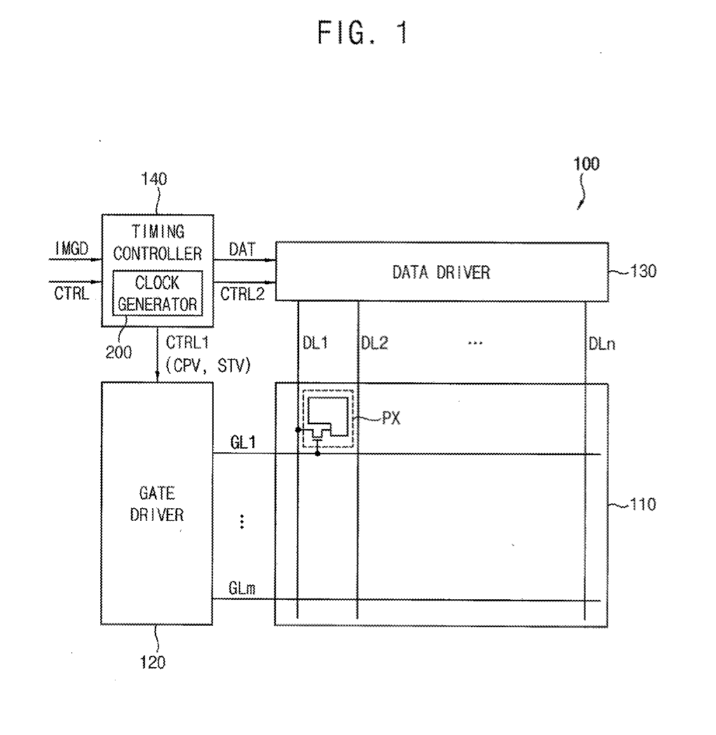

FIG. 1 is a block diagram illustrating a display device according to example embodiments.

Referring to FIG. 1, a display device 100 includes a display panel 110 including a plurality of pixels PX, a gate driver 120 providing gate signals to the plurality of pixels PX, a data driver 130 providing data signals to the plurality of pixels PX, and a timing controller 140 controlling the gate driver 120 and the data driver 130.

The display panel 110 may include a plurality of gate lines (e.g., GL1, . . . , and GLm), a plurality of data lines (e.g., DL1, DL2, . . . , and DLn). In the display panel, the plurality of pixels PX is coupled to the plurality of gate lines (e.g., GL1, . . . , and GLm) and the plurality of data lines (e.g., DL1, DL2, . . . , and DLn). In some example embodiments, as illustrated in FIG. 1, each pixel PX may include a switching transistor and a liquid crystal cell coupled to the switching transistor, and the display panel 110 may be a liquid crystal display (LCD) panel. In other example embodiments, each pixel PX may include a switching transistor, at least another transistor, at least one capacitor and an organic light emitting diode (OLED), and the display panel 110 may be an OLED display panel. The display panel 110 may also be a type of a display panel other than LCD or OLED types.

The gate driver 120 may generate the gate signals based on a gate control signal CTRL1 from the timing controller 140, and may sequentially apply the gate signals to the gate lines from GL1 to GLm. In some example embodiments, the gate control signal CTRL1 may include, but not limited to, a gate clock signal CPV and a scan start pulse STV. According to example embodiments, the gate driver 120 may be mounted directly on the display panel 110, may be connected to the display panel 110 in a form of a tape carrier package (TCP), or may be integrated in a peripheral portion of the display panel 110.

The data driver 130 may generate the data signals that are analog data voltages based on digital data DAT and a data control signal CTRL2 from the timing controller 140, and may apply the data signals to the data lines (e.g., DL1, DL2, . . . , and DLn). In some example embodiments, the data control signal CTRL2 may include, but not limited to, a horizontal start signal and a load signal. According to example embodiments, the data driver 130 may be mounted directly on the display panel 110, may be connected to the display panel 110 in a form of a TCP, or may be integrated in a peripheral portion of the display panel 110.

The timing controller 140 may receive input image data IMGD and an input control signal CTRL from an external host (e.g., a graphic processing unit (GPU)). In some example embodiments, the input image data IMGD may include red image data, green image data and blue image data. In some example embodiments, the input control signal CTRL may include, but not limited to, a data enable signal, a vertical synchronization signal, a horizontal synchronization signal and a master clock signal. The timing controller 140 may generate the gate control signal CTRL1, the data control signal CTRL2 and the digital data DAT based on the input image data IMGD and the input control signal CTRL. The timing controller 140 may control the operation of the gate driver 120 by providing the gate control signal CTRL1 to the gate driver 120, and may control the operation of the data driver 130 by providing the digital data DAT and the data control signal CTRL2 to the data driver 130. The gate control signal CTRL1 may be generated at an output terminal of the timing controller 140.

The timing controller 140 may include a clock generator 200 that may generates the gate clock signal CPV provided to the gate driver 120 based on the master clock signal provide from the external host or an internal clock signal generated by the timing controller 140. The clock generator 200 may be a spread spectrum clock generator that spreads power of the gate clock signal CPV by changing a time period of the gate clock signal CPV as time progresses (i.e., modulating the gate clock signal CPV). Thus, because of the time period modulation, the power of the gate clock signal CPV transferred between the timing controller 140 and the gate driver 120 is spread in a frequency domain, and electro-magnetic interference (EMI) caused by the display device 100 may be reduced. In some example embodiments, modulation of the gate clock signal CPV may involve changing both a time period and a duty cycle of the gate clock signal CPV as time progresses. In the present disclosure, a frequency of the gate clock signal CPV at a time may be defined as the inverse of the time period of the gate clock signal CPV at the same time, and modulating the gate clock signal CPV includes changing at least a time period of the gate clock signal CPV (or equivalently, changing at least a frequency of the gate clock signal CPV).

In some example embodiments, the clock generator 200 may modulate the gate clock signal CPV with a first modulation pattern in a first frame period, and may modulate the gate clock signal CPV with a second modulation pattern different from the first modulation pattern in a second frame period. In some example embodiments, when the first modulation pattern and the second modulation pattern are in a periodic form that includes one or more cycles with an identifiable modulation time period, these two modulation patterns may be different in at least one of modulation period (MP) (or modulation frequency (MF)), modulation amount (or modulation ratio (MR) that is a ratio of the modulation amount to a reference frequency) and modulation phase from each other.

In some example embodiments, a phase of the second modulation pattern may be different by about 180 degrees from a phase of the first modulation pattern. In some example embodiments, the second modulation pattern may be an inverted version of the first modulation pattern, which is inverted from the first modulation pattern with respect to a reference frequency. Because the modulation pattern inversion, if the gate clock signal CPV modulated with the first modulation pattern in the first frame period has a frequency higher than a reference frequency at a time point when a gate signal for one gate line of the plurality of gate lines (e.g., GL1 to GLm) is generated, the gate clock signal CPV modulated with the second modulation pattern in the second frame period has a frequency lower than the reference frequency at a time point when the gate signal for the one gate line is generated. Accordingly, the gate signal applied to the one gate line in the first frame period may have a width narrower than a reference width, and thus the pixels PX coupled to the one gate line may have a relatively low charging amount in the first frame period. However, the gate signal applied to the one gate line in the second frame period may have a width wider than the reference width, and thus the pixels PX coupled to the one gate line may have a relatively high charging amount in the second frame period. Accordingly, although the gate clock signal CPV is modulated, or although the frequency of the gate clock signal CPV is constantly changed, a horizontal line defect and/or a black noise caused by the modulation of the gate clock signal CPV may be reduced.

In a conventional display device employing a spread spectrum clock generator, when a frequency of a clock signal generated by the spread spectrum clock generator is changed and a width of the clock signal becomes narrower, a width of a gate signal that is applied sequentially to a plurality of gate lines becomes more and more narrow; consequently, luminance of pixel rows respectively corresponding to the gate lines may gradually become darker along a vertical direction, which forms horizontal line defects. Further, in a conventional display device, when average luminance of a portion of a display panel is different from average luminance of another portion of the display panel, black noise may occur.

In contrast, in the display device 100 according to example embodiments of present disclosure, the timing controller 140 may modulate the gate clock signal CPV with the first modulation pattern in the first frame period, and may modulate the gate clock signal CPV with the second modulation pattern different from the first modulation pattern in the second frame period; such modulation of the gate clock signal CPV reduces the horizontal line defect or the black while reducing the EMI.

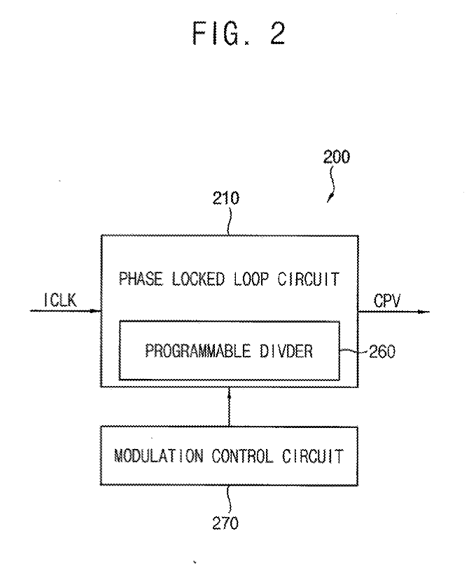

FIG. 2 is a block diagram illustrating a clock generator included in a timing controller according to example embodiments.

Referring to FIG. 2, a clock generator 200 may include a phase locked loop circuit 210 that generates a gate clock signal CPV based on an input clock signal ICLK, and a modulation control circuit 270 that controls the phase locked loop circuit 210 to modulate the gate clock signal CPV.

The phase locked loop circuit 210 may receive, as the input clock signal ICLK, a master clock signal provided from an external host or an internal clock signal generated inside a timing controller including the clock generator 200. The phase locked loop circuit 210 may generate the gate clock signal CPV based on the master clock signal or the internal clock signal, and may provide the gate clock signal CPV to a gate driver. The phase locked loop circuit 210 may include a programmable divider 260, and the modulation control circuit 270 control the phase locked loop circuit 210 to modulate the gate clock signal CPV by changing a divider value of the programmable divider 260.

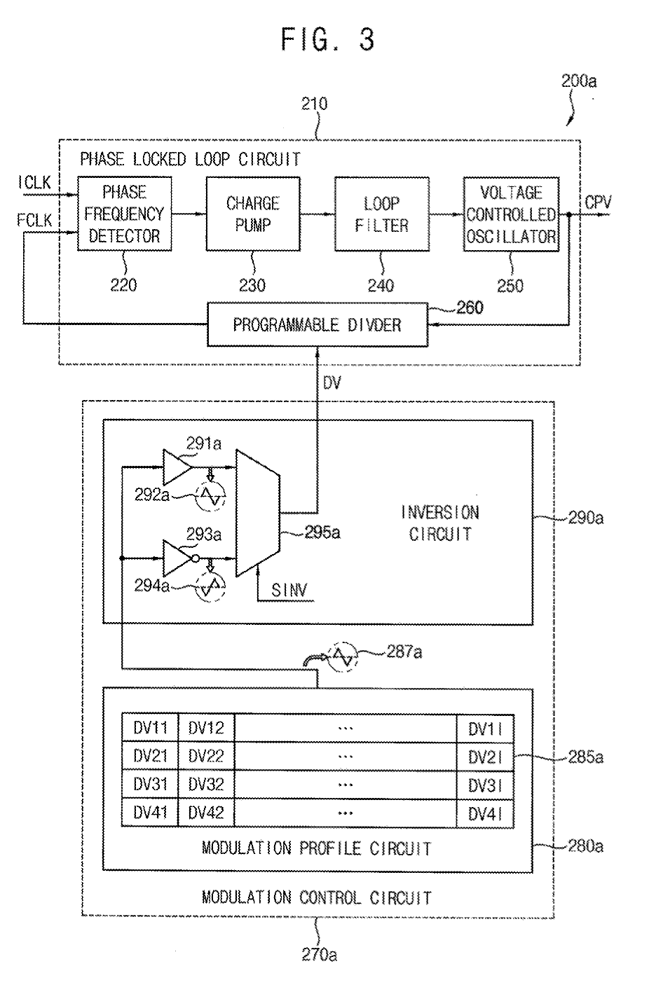

FIG. 3 is a block diagram illustrating a clock generator included in a timing controller according to example embodiments.

Referring to FIG. 3, a clock generator 200a may include a phase locked loop circuit 210 that generates a gate clock signal CPV based on an input clock signal ICLK, and a modulation control circuit 270a that controls the phase locked loop circuit 210 to modulate the gate clock signal CPV.

The phase locked loop circuit 210 may include a phase frequency detector 220 that generates an error signal corresponding to a phase difference (and/or a frequency difference) between the input clock signal ICLK and a feedback clock signal FCLK, a charge pump 230 that generates a current corresponding to the error signal, a loop filter 240 that converts the current generated by the charge pump 230 into a control voltage, a voltage controlled oscillator 250 that generates the gate clock signal CPV having a frequency corresponding to the control voltage, and a programmable divider 260 that receives a divider value DV from the modulation control circuit 270a and generates the feedback clock signal FCLK by dividing the gate clock signal CPV by the received divider value DV. It is to be appreciated that a configuration of the phase locked loop circuit 210 as described above is illustrative for an embodiment of the present inventive concept and not limited to a configuration as illustrated in FIG. 3.

The modulation control circuit 270a may include a modulation profile circuit 280a that stores a reference modulation pattern 287a, and an inversion circuit 290a that outputs the reference modulation pattern 287a as a first modulation pattern 292a in a first frame period and inverts the reference modulation pattern 287a to output an inverted reference modulation pattern as the second modulation pattern 294a in a second frame period.

In some example embodiments, the modulation profile circuit 280a may include a divider value table 285a that stores a plurality of divider values, for example, divider values for a first sub-period SP1 (e.g., DV11, DV12, . . . , and DV11), divider values for a second sub-period SP2 (e.g., DV21, DV22, . . . , and DV21), divider values for a third sub-period SP3 (e.g., DV31, DV32, . . . , and DV31), and divider values for a fourth sub-period SP4 (e.g., DV41, DV42, . . . , and DV41); these divider values may be used to generate the reference modulation pattern 287a. The inversion circuit 290a may include a buffer 291a that buffers the divider values (e.g., DV11, DV12, . . . , and DV11 for SP1; DV21, DV22, . . . , and DV21 for SP2; DV31, DV32, . . . , and DV31 for SP3; DV41, DV42, . . . , and DV41 for SP4) sequentially output from the divider value table 285a, an inverter 293a that inverts the divider values (e.g., DV11, DV12, . . . , and DV11 for SP1; DV21, DV22, . . . , and DV21 for SP2; DV31, DV32, . . . , and DV31 for SP3; DV41, DV42, . . . , and DV41 for SP4) sequentially output from the divider value table 285a, and a multiplexer 295a that selectively outputs the buffered divider values output from the buffer 291a or the inverted divider values output from the inverter 293a in response to a modulation control signal SINV that is inverted after each frame period.

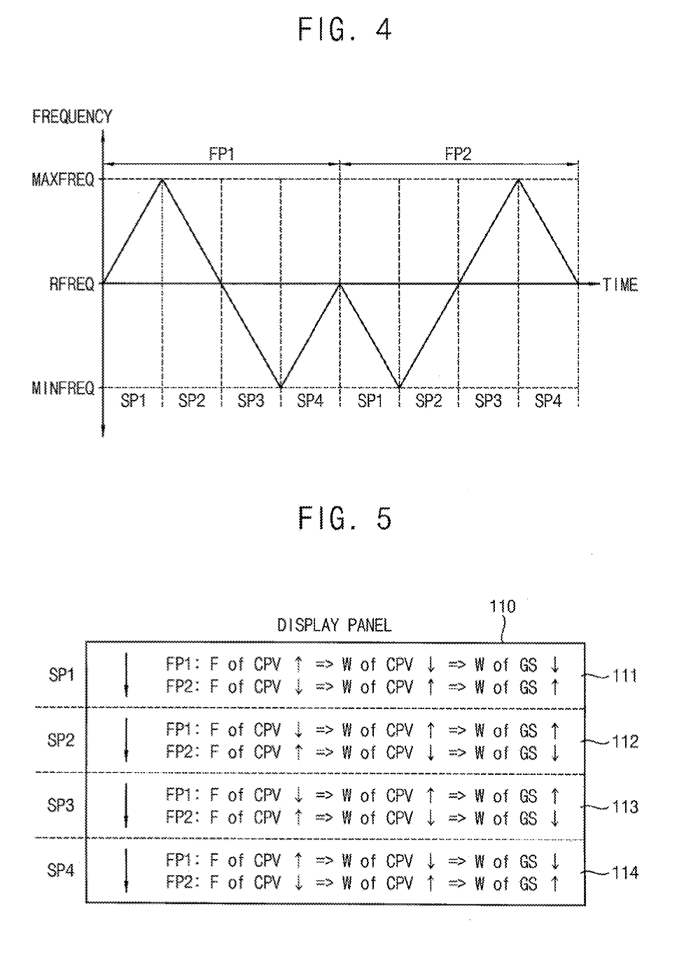

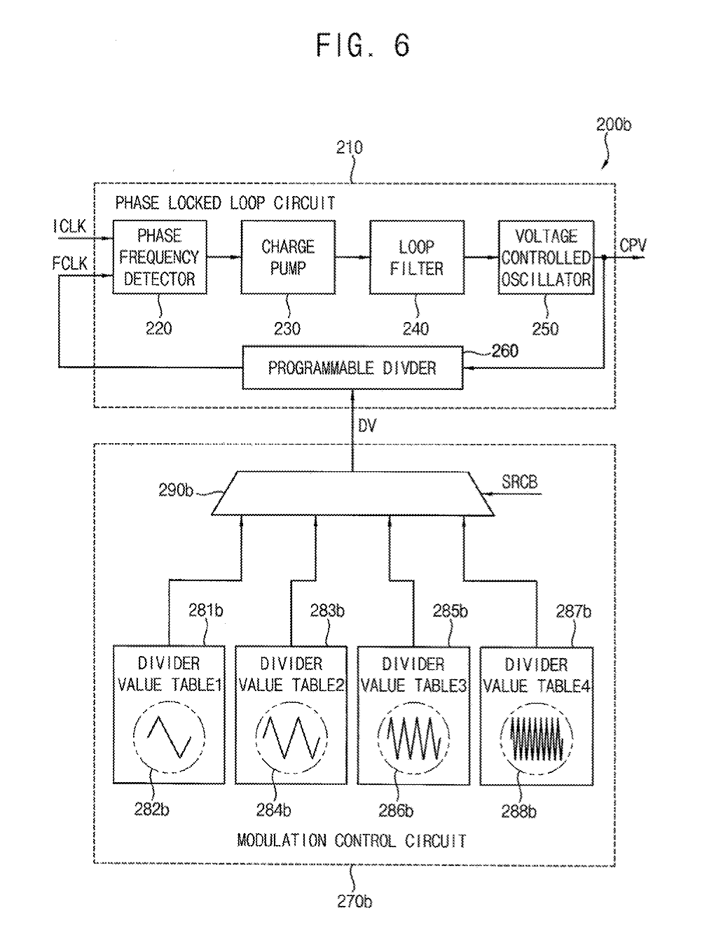

Hereinafter, an example of an operation of the clock generator 200a will be described below with reference to FIGS. 4 and 5.

FIG. 4 is a timing diagram illustrating an example of a frequency of a gate clock signal generated by a clock generator included in a timing controller according to example embodiments, and FIG. 5 is a diagram of a display panel for describing an effect of reducing a horizontal line defect of a black noise by a gate clock signal having a frequency illustrated in FIG. 4.

Referring to FIGS. 3 through 5, the clock generator 200a may modulate the gate clock signal CPV with the first modulation pattern 292a in the first frame period FP 1, and may modulate the gate clock signal CPV with the second modulation pattern 294a in the second frame period FP2. In some example embodiments, as illustrated in FIGS. 5 and 6, a modulation period of each of the first and second frame periods FP1 and FP2 may be substantially the same as one frame period. Further, each of the first and second frame periods FP I and FP2 may be equally divided into a first sub-period SP1, a second sub-period SP2, a third sub-period SP3 and a fourth sub-period SP4. For purposes of illustration, supposing that a display panel 110 is equally divided into first through fourth regions 111, 112, 113 and 114, a gate signal may be sequentially applied to the first region 111 of the display panel 110 during the first sub-period SP1, may be sequentially applied to the second region 112 of the display panel 110 during the second sub-period SP2, may be sequentially applied to the third region 113 of the display panel 110 during the third sub-period SP3, and may be sequentially applied to the fourth region 114 of the display panel 110 during the fourth sub-period SP4.

The divider value table 285a of the modulation profile circuit 280a may store, as the reference modulation pattern 287a, gradually increasing divider values DV11, DV12, . . . , and DV11 corresponding to the first sub-period SP1, gradually decreasing divider values DV21, DV22, . . . , and DV21 corresponding to the second sub-period SP2, gradually decreasing divider values DV31, DV32, . . . , and DV31 corresponding to the third sub-period SP3, and gradually increasing divider values DV41, DV42, . . . , and DV41 corresponding to the fourth sub-period SP4.

In the first frame period FP1, the modulation profile circuit 280a may sequentially output the divider values (e.g., DV11, DV12, . . . , and DV11 for SP1; DV21, DV22, . . . , and DV21 for SP2; DV31, DV32, . . . , and DV31 for SP3; DV41, DV42, . . . , and DV41 for SP4), the buffer 291a of the inversion circuit 290a may buffer these divider values, and the multiplexer 295a of the inversion circuit 290a may provide an output of the buffer 291a to the programmable divider 260 of the phase locked loop circuit 210 in response to the modulation control signal SIMV having a first logic level (e.g. a value of 0). The programmable divider 260 may generate the feedback clock signal FCLK by dividing the gate clock signal CPV using the divider values (e.g., DV11, DV12, . . . , and DV11 for SP1; DV21, DV22, . . . , and DV21 for SP2; DV31, DV32, and DV31 for SP3; DV41, DV42, . . . , and DV41 for SP4) that are sequentially provided. Based on the feedback clock signal FCLK generated as described above, the phase locked loop circuit 210 may generate the gate clock signal CPV having a frequency F that increases from a reference frequency RFREQ to a maximum frequency MAXFREQ during the first sub-period SP1 of the first frame period FP1, decreases from the maximum frequency MAXFREQ to the reference frequency RFREQ during the second sub-period SP2 of the first frame period FP1, decreases from the reference frequency RFREQ to a minimum frequency MINFREQ during the third sub-period SP3 of the first frame period FP1, and increases from the minimum frequency MINFREQ to the reference frequency RFREQ during the fourth sub-period SP4 of the first frame period FP1.

Further, in the second frame period FP2, the modulation profile circuit 280a may sequentially output the divider values (e.g., DV11, DV12, . . . , and DV11 for SP1; DV21, DV22, . . . , and DV21 for SP2; DV31, DV32, . . . , and DV31 for SP3; DV41, DV42, . . . , and DV41 for SP4), the inverter 293a of the inversion circuit 290a may invert the these divider values to sequentially output inverted divider values, and the multiplexer 295a of the inversion circuit 290a may provide an output of the inverter 293a to the programmable divider 260 of the phase locked loop circuit 210 in response to the modulation control signal SINV having a second logic level (e.g. a value of 1). The programmable divider 260 may generate the feedback clock signal FCLK by dividing the gate clock signal CPV using the inverted divider values that are sequentially provided. Based on the feedback clock signal FCLK generated as described above, the phase locked loop circuit 210 may generate the gate clock signal CPV having a frequency F that decreases from the reference frequency RFREQ to the minimum frequency MINFREQ during the first sub-period SPI of the second frame period FP2, increases from the minimum frequency MINFREQ to the reference RFREQ frequency during the second sub-period SP2 of the second frame period FP2, increases from the reference frequency RFREQ to the maximum frequency MAXFREQ during the third sub-period SP3 of the second frame period FP2, and decreases from the maximum frequency MAXFREQ to the reference frequency RFREQ during the fourth sub-period SP4 of the second frame period FP2.

As illustrated in FIG. 5, with respect to the first region 111 of the display panel 110 during the first sub-period SP1 of the first frame period FP1, the frequency F of the gate clock signal CPV may increase, a width W of the gate clock signal CPV may decrease along a vertical direction, and thus a width W of a gate signal GS may gradually decrease. Accordingly, in the first frame period FP1, charging amounts of pixel rows in the first region 111 of the display panel 110 may gradually decrease, and luminances of the pixel rows may gradually get darker along the vertical direction. However, during the first sub-period SP1 of the second frame period FP2, the frequency F of the gate clock signal CPV may decrease, the width W of the gate clock signal CPV may increase along the vertical direction, and thus the width W of the gate signal GS applied to the first region 111 of the display panel 110 may gradually increase. Accordingly, in the second frame period FP2, the charging amounts of the pixel rows in the first region 111 of the display panel 110 may gradually increase, and the luminances of the pixel rows may gradually get brighter along the vertical direction, which results in the compensation for the luminance change in the first frame period FP1 during the first frame period FP1.

During the second sub-period SP2 of the first frame period FP1, the frequency F of the gate clock signal CPV may decrease, the width W of the gate clock signal CPV may increase along the vertical direction, and thus the width W of the gate signal GS may gradually increase. However, during the second sub-period SP2 of the second frame period FP2, the frequency F of the gate clock signal CPV may increase, the width W of the gate clock signal CPV may decrease along the vertical direction, and thus the width W of the gate signal GS may gradually decrease. Further, during the third sub-period SP3 of the first frame period FP 1, the frequency F of the gate clock signal CPV may decrease, the width W of the gate clock signal CPV may increase along the vertical direction, and thus the width W of the gate signal GS may gradually increase. However, during the third sub-period SP3 of the second frame period FP2, the frequency F of the gate clock signal CPV may increase, the width W of the gate clock signal CPV may decrease along the vertical direction, and thus the width W of the gate signal GS may gradually decrease. Further, during the fourth sub-period SP4 of the first frame period FP1, the frequency F of the gate clock signal CPV may increase, the width W of the gate clock signal CPV may decrease along the vertical direction, and thus the width W of the gate signal GS may gradually decrease. However, during the fourth sub-period SP4 of the second frame period FP2, the frequency F of the gate clock signal CPV may decrease, the width W of the gate clock signal CPV may increase along the vertical direction, and thus the width W of the gate signal GS may gradually increase. Accordingly, the luminance change in the first frame period FP1 may be compensated during the second sub-period SP2, the third sub-period SP3, and the fourth sub-period SP4.

As described above, the clock generator 200a of the timing controller may modulate the gate clock signal CPV with the first modulation pattern 292a in the first frame period FP1, and may modulate the gate clock signal CPV with the second modulation pattern 294a that is inverted from the first modulation pattern 292a in the second frame period FP2, thus reducing the horizontal line defect or the black noise caused by the modulation of the gate clock signal CPV while reducing the EMI.

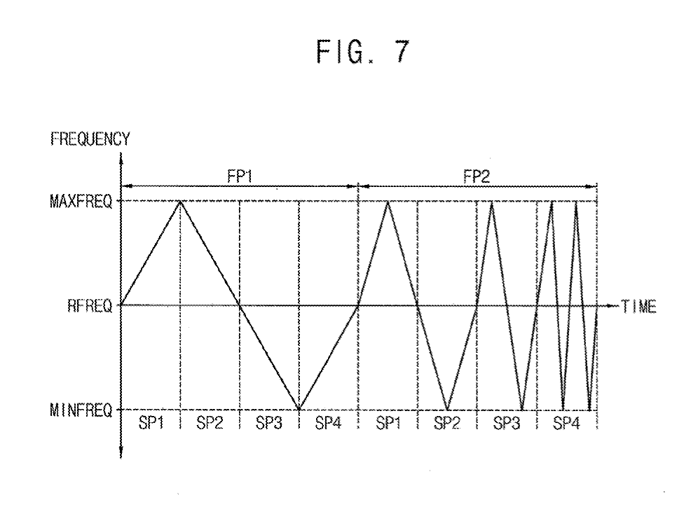

FIG. 6 is a block diagram illustrating a clock generator included in a timing controller according to example embodiments, and FIG. 7 is a timing diagram illustrating an example of a frequency of a gate clock signal generated by a clock generator included in a timing controller according to example embodiments.

Referring to FIG. 6, a clock generator 200b according to example embodiments may include a phase locked loop circuit 210 that generates a gate clock signal CPV based on an input clock signal ICLK, and a modulation control circuit 270b that controls the phase locked loop circuit 210 to modulate the gate clock signal CPV. The clock generator 200b of FIG. 6 may have a similar configuration to a clock generator 200a of FIG. 6, except for a configuration of the modulation control circuit 270b.

The clock generator 200b may store a plurality of modulation patterns (e.g., 282b, 284b, 286b and 288b) and sequentially (or rotationally) select this plurality of modulation patterns for generating a clock signal CPV. The clock generator 200b may modulate the gate clock signal CPV with the sequentially selected modulation patterns (i.e., 282b, 284b, 286b and 288b) and provide a gate driver with the clock signal CPV. To perform these operations, the modulation control circuit 270b of the clock generator 200b may store the plurality of modulation patterns (i.e., 282b, 284b, 286b and 288b), sequentially select the plurality of modulation patterns (i.e., 282b, 284b, 286b and 288b), and control the phase locked loop circuit 210 to modulate the gate clock signal CPV with the sequentially selected modulation patterns (i.e., 282b, 284b, 286b and 288b).

In some example embodiments, the modulation control circuit 270b may include a plurality of divider value tables (e.g., 281b, 283b, 285b and 287b) each storing a plurality of divider value sets for specifying a corresponding modulation pattern in the plurality of modulation patterns (i.e., 282b, 284b, 286b and 288b). The modulation control circuit 270b may include a multiplexer 290b that selectively outputs one of the plurality of divider value DV sets output from the plurality of divider value tables 281b, 283b, 285b and 287b in response to a rotational control bit signal SRCB.

In some example embodiments, when each of the modulation patterns (e.g., 282b, 284b, 286b and 288b) in the clock generator 200b is in a periodic form that includes one or more cycles with an identifiable modulation time period, these modulation patterns may be different in at least one of modulation period, modulation amount and modulation phase from each other. In some example embodiments, the plurality of modulation patterns 282b, 284b, 286b and 288b may include a first modulation pattern 282b having a modulation period corresponding to one frame period, a second modulation pattern 286b having a modulation period corresponding to a half of a frame period, a third modulation pattern 286b having a modulation period corresponding to a quarter of a frame period, and a fourth modulation pattern 288b having a modulation period corresponding to one-eighth of a frame period. In this case, as illustrated in FIG. 7, the clock generator 200b may modulate the gate clock signal CPV with the first modulation pattern 282b during a first frame period FP 1, may modulate the gate clock signal CPV with the second modulation pattern 284b during first and second sub-periods SP1 and SP2 of a second frame period FP2, may modulate the gate clock signal CPV with the third modulation pattern 286b during the third sub-period SP3 of the second frame period FP2, and may modulate the gate clock signal CPV with the fourth modulation pattern 288b during the fourth sub-period SP4 of the second frame period FP2.

As described above, the clock generator 200b of the timing controller may sequentially or rotationally select the plurality of modulation patterns 282b, 284b, 286b and 288b that are different in at least one of modulation period, modulation amount and modulation phase. the clock generator 200b may modulate the gate clock signal CPV with the sequentially or rotationally selected modulation patterns 282b, 284b, 286b and 288b, thus reducing the horizontal line defect or the black noise caused by the modulation of the gate clock signal while reducing the EMI.

The example embodiments of the inventive concepts may be applied to any display device and any electronic device including the display device. For example, the example embodiments of the inventive concepts may be applied to a television (TV), a digital TV, a 3D TV, a smart phone, a mobile phone, a tablet computer, a personal computer (PC), a home appliance, a laptop computer, a personal digital assistant (PDA), a portable multimedia player (PMP), a digital camera, a music player, a portable game console, a navigation device, etc.

The foregoing is illustrative of example embodiments and is not to be construed as limiting thereof. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A timing controller comprising:
an output terminal operative to provide a gate clock signal to a gate driver of a display device; and
a clock generator operative to generate the gate clock signal by modulating the gate clock signal with a first modulation pattern in a first frame period and by modulating the gate clock signal with a second modulation pattern different from the first modulation pattern in a second frame period.

2. The timing controller of claim 1, wherein the first modulation pattern and the second modulation pattern are different in at least one of modulation period, modulation amount and modulation phase from each other.

3. The timing controller of claim 1, wherein the second modulation pattern is inverted from the first modulation pattern with respect to a reference frequency.

4. The timing controller of claim 3, wherein, if the gate clock signal modulated with the first modulation pattern in the first frame period has a frequency higher than a reference frequency at a time point when a gate signal for one gate line of a plurality of gate lines is generated, the gate clock signal modulated with the second modulation pattern in the second frame period has a frequency lower than the reference frequency at a corresponding time point when the gate signal for the same one gate line is generated.

5. The timing controller of claim 1, wherein a modulation period of the first and second modulation patterns is substantially identical to one frame period.

6. The timing controller of claim 1, wherein each of the first and second frame periods is equally divided into a first sub-period, a second sub-period, a third sub-period and a fourth sub-period,
wherein a frequency of the gate clock signal modulated with the first modulation pattern increases from a reference frequency to a maximum frequency during the first sub-period of the first frame period, decreases from the maximum frequency to the reference frequency during the second sub-period of the first frame period, decreases from the reference frequency to a minimum frequency during the third sub-period of the first frame period, and increases from the minimum frequency to the reference frequency during the fourth sub-period of the first frame period, and
wherein the frequency of the gate clock signal modulated with the second modulation pattern decreases from the reference frequency to the minimum frequency during the first sub-period of the second frame period, increases from the minimum frequency to the reference frequency during the second sub-period of the second frame period, increases from the reference frequency to the maximum frequency during the third sub-period of the second frame period, and decreases from the maximum frequency to the reference frequency during the fourth sub-period of the second frame period.

7. The timing controller of claim 1, wherein the clock generator comprises:
a phase locked loop circuit configured to generate the gate clock signal in response to an input clock signal; and
a modulation control circuit configured to control the phase locked loop circuit to modulate the gate clock signal.

8. The timing controller of claim 7, wherein the phase locked loop circuit includes a programmable divider, and
wherein the modulation control circuit controls the phase locked loop circuit to modulate the gate clock signal by changing a divider value of the programmable divider.

9. The timing controller of claim 7, wherein the phase locked loop circuit comprises:
a phase frequency detector configured to generate an error signal corresponding to a phase difference between the input clock signal and a feedback clock signal;
a charge pump configured to generate a current corresponding to the error signal;
a loop filter configured to convert the current generated by the charge pump into a control voltage;
a voltage controlled oscillator configured to generate the gate clock signal having a frequency corresponding to the control voltage; and
a programmable divider configured to receive a divider value from the modulation control circuit, and to generate the feedback clock signal by dividing the gate clock signal by the received divider value.

10. The timing controller of claim 7, wherein the modulation control circuit comprises:
a modulation profile circuit configured to store a reference modulation pattern; and
an inversion circuit configured to output the reference modulation pattern as the first modulation pattern in the first frame period, and to invert the reference modulation pattern with respect to a reference frequency to output the inverted reference modulation pattern as the second modulation pattern in the second frame period.

11. The timing controller of claim 10, wherein the modulation profile circuit comprises:
a divider value table configured to store a plurality of divider values corresponding to the reference modulation pattern.

12. The timing controller of claim 11, wherein the inversion circuit comprises:
a buffer configured to buffer the divider values sequentially output from the divider value table;
an inverter configured to invert the divider values sequentially output from the divider value table; and
a multiplexer configured to selectively output the buffered divider values output from the buffer or the inverted divider values output from the inverter in response to a modulation control signal that is inverted after each frame period.

13. A timing controller comprising:
an output terminal operative to provide a gate clock signal to a gate driver of a display device; and
a clock generator configured to store a plurality of modulation patterns, to sequentially select the plurality of modulation patterns, to modulate the gate clock signal with a selected one of the plurality of modulation patterns.

14. The timing controller of claim 13, wherein the plurality of modulation patterns are different in at least one of modulation period, modulation amount and modulation phase from each other.

15. The timing controller of claim 13, wherein the plurality of modulation patterns include a first modulation pattern having a modulation period corresponding to one frame period, a second modulation pattern having a modulation period corresponding to a half of a frame period, a third modulation pattern having a modulation period corresponding to a quarter of a frame period, and a fourth modulation pattern having a modulation period corresponding to one-eighth of a frame period.

16. The timing controller of claim 15, wherein each frame period is equally divided into a first sub-period, a second sub-period, a third sub-period and a fourth sub-period, and
wherein the clock generator modulates the gate clock signal with the first modulation pattern during a first frame period, modulates the gate clock signal with the second modulation pattern during the first and second sub-periods of a second frame period, modulates the gate clock signal with the third modulation pattern during the third sub-period of the second frame period, and modulates the gate clock signal with the fourth modulation pattern during the fourth sub-period of the second frame period.

17. The timing controller of claim 13, wherein the clock generator comprises:
a phase locked loop circuit configured to generate the gate clock signal in response to an input clock signal; and
a modulation control circuit configured to store the plurality of modulation patterns, to sequentially select the plurality of modulation patterns, and to control the phase locked loop circuit to modulate the gate clock signal with the selected one of the plurality of modulation patterns.

18. The timing controller of claim 17, wherein the modulation control circuit comprises:
a plurality of divider value tables configured to store a plurality of divider value sets corresponding to the plurality of modulation patterns, respectively; and
a multiplexer configured to selectively output one of the plurality of divider value sets output from the plurality of divider value tables in response to a rotational control bit signal.

19. A display device comprising:
a display panel including a plurality of data lines, a plurality of gate lines, and a plurality of pixels, wherein a pixel includes a switching transistor having a gate thereof connected to a gate line;
a data driver configured to provide data signals to the plurality of pixels through the plurality of data lines;
a gate driver configured to provide gate signals to the plurality of pixels through the plurality of gate lines; and
a timing controller configured to control the data driver and the gate driver, the timing controller comprising:
a clock generator configured to provide a gate clock signal to the gate driver by modulating the gate clock signal with a first modulation pattern in a first frame period and by modulating the gate clock signal with a second modulation pattern different from the first modulation pattern in a second frame period.

20. The display device of claim 19, wherein the second modulation pattern is inverted from the first modulation pattern with respect to a reference frequency.
